(19) United States
(12) Patent Application Publication
(10) Pub. No.: US 2021/0406415 A1
(43) Pub. Date: Dec. 30, 2021

(54) CONSTRUCTION MODEL CREATION SYSTEM, CONSTRUCTION MODEL CREATING METHOD, CONSTRUCTION INSPECTION SYSTEM, CONSTRUCTION INSPECTING METHOD

(71) Applicant: TOPCON CORPORATION, Tokyo (JP)

(72) Inventors: Atsushi DOJI, Tokyo (JP); Satoshi YANOBE, Tokyo (JP); Toshio YAMADA, Tokyo (JP)

(21) Appl. No.: 17/348,874

(22) Filed: Jun. 16, 2021

(30) Foreign Application Priority Data
Jun. 24, 2020 (JP) 2020-108763

(51) Int. Cl. G06F 30/13; G06F 16/29

(52) U.S. Cl. CPC G06F 30/13; G06F 16/29

(57) ABSTRACT

For creation of a construction model, a construction model creation system of the present invention includes a work results database storing position coordinates of work results, a work results extracting unit configured to extract the work results that are necessary from the work results database, a model creating unit configured to create a model from the extracted work results, a model determining unit configured to store a determined element of the model created by the model creating unit as a construction model of the construction work, and a construction model database configured to store the construction model determined by the model determining unit.

### TECHNICAL FIELD

The present invention relates to a system for creating a construction model of a construction work at a construction site, and a system for conducting a construction quality inspection based on the model.

### BACKGROUND ART

For construction work and plant construction work, etc., construction works such as reinforced concrete floors, ceilings, and walls, etc., are provided and in recent years, these construction works are designed by using 3D models called BIM (Building Information Modeling). In these types of work, an inspection is conducted to confirm that a construction work is constructed as designed by BIM. In the inspection, a construction work for which a worker performed a work was inspected by visual confirmation by a builder and/or a designer or by referring to measurement data obtained by measuring the construction work by a laser scanner, etc., as described in Patent Literature 1.

### CITATION LIST

### Patent Literature

[Patent Literature 1] Japanese Published Unexamined Patent Application No. 2019-45962

### SUMMARY OF INVENTION

### Technical Problem

However, in the inspection conducted by the method described above, a workload for performing a measurement for the inspection was placed on the builder, etc. In addition, the measurement and the inspection were performed separately, and data were not linked to each other, and for example, when a fault was found through the inspection, a large-scale on-site confirmation work was required in some cases.

The present invention has been made in view of this problem, and an object thereof is to provide a system, etc., for enabling an inspection using a construction model of a construction work by automatically generating the construction model from work results obtained at the time of construction.

### Solution to Problem

In order to solve the problem described above, a construction model creating method according to an aspect of the present invention creates a construction model of a construction work based on data of work results that a worker performed with a tool at a construction site.

In order to solve the problem, a construction model creating method according to another aspect of the present invention includes the steps of, by transmitting and receiving information to and from a work results database storing position coordinates of work results of a construction work performed by a worker with a tool at a construction site, (A) extracting the work results necessary for model creation of a construction work from the work results database, (B) creating a model from the work results extracted in the step A, and (C) storing a determined element of the model created in the step B as a construction model of the construction work in a construction model database.

In the aspect described above, it is also preferable that, further, by transmitting and receiving information to and from a member shape database storing data on member shape patterns, in the step B, with reference to the member shape database, the model is created according to a member shape of the construction work as a model creating target.

In the aspect described above, it is also preferable that based on the member shape pattern stored in the member shape database, at least a linear shaped, quadrangular shaped, or circular shaped model is created in the step B.

In the aspect described above, it is also preferable that, further, by transmitting and receiving information to and from a drawing database storing member coordinate data obtained from a design drawing, in the step A, with reference to the drawing database, the work results are extracted based on coordinates of the construction work as a model creating target in the design drawing.

In the aspect described above, it is also preferable that, further, in the step B, a work starting point foreign to a specific creation processing is excluded from the work results extracted in the step B, and stored as a singular point in the step C, and by using the singular point as new extracted work results, model creation processing is recursively performed.

In the aspect described above, it is also preferable that the work results database stores attributes information of at least a work time, a worker, or a tool, and in the step A, the work results are extracted according to the attributes information.

A construction inspecting method is also preferable, which includes the steps of (D) selecting an inspection target model from the construction model database, (E) selecting confirmation content for the inspection target model by transmitting and receiving information to and from a drawing database storing member coordinate data and confirmation content data obtained from a design drawing, (F) establishing a correspondence between a component of the inspection target model and a component in the design drawing, (G) confirming whether the component of the inspection target model meets the confirmation content for the corresponding component in the design drawing, and (H) notifying a work fault when the confirmation content is not met in the step G.

Further, in order to solve the problem described above, a construction model creation system according to an aspect of the present invention includes a work results database storing position coordinates of work results of a construction work performed by a worker with a tool at a construction site, a work results extracting unit configured to extract the work results necessary for model creation of a construction work from the work results database, a model creating unit configured to create a model from the extracted work results extracted by the work results extracting unit, a model determining unit configured to store a determined element of the model created by the model creating unit as a construction model of the construction work, and a construction model database configured to store the construction model determined by the model determining unit.

In the aspect described above, it is also preferable that the construction model creation system further includes a member shape database storing data on member shape patterns, wherein the model creating unit refers to the member shape database and creates the model according to a member shape of the construction work as a model creating target.

In the aspect described above, it is also preferable that the construction model creation system further includes a drawing database storing member coordinate data obtained from a design drawing, wherein the work results extracting unit refers to the drawing database and extracts the work results based on coordinates of the construction work as a model creating target in the design drawing.

In the aspect described above, it is also preferable that the construction model creation system further includes a singular point processing unit configured to exclude a work starting point foreign to a specific model creation processing of the model creating unit from the work results extracted and treat the work starting point as a singular point.

A construction inspection system is also preferable, which includes a model inspecting unit configured to select an inspection target model from the construction model database, select the confirmation content from a drawing database storing member coordinate data and confirmation content data obtained from a design drawing, establish a correspondence between a component of the inspection target model and a component in the design drawing, confirm whether the component of the inspection target model meets the confirmation content for the corresponding component in the design drawing, and notify a work fault when the confirmation content is not met.

Further, a construction model creation program is also preferable, which describes the construction model creating method of the aspect described above as a computer program to enable execution of the method.

A construction inspection program is also preferable, which describes the construction inspecting method according to the aspect described above as a computer program to enable execution of the method.

### Effect of Invention

By the construction model creation system, etc., of the present invention, a construction model of a construction work can be automatically generated from work results obtained at the time of construction.

### BRIEF DESCRIPTION OF DRAWINGS

FIG. 1 is a configuration block diagram of a construction model creation system according to a first embodiment.

FIG. 2A is an example of a work results database in the same system. FIG. 2B is another example of the work results database in the same system. FIG. 2C is still another example of the work results database in the same system.

FIG. 3A is an example of a construction model database in the same system. FIG. 3B is another example of the construction model database in the same system. FIG. 3C is still another example of the construction model database in the same system.

FIG. 4 is a creation flowchart of a construction model creating method according to the first embodiment.

FIG. 5 is a detailed flowchart of model creation processing in the same construction model creating method.

FIG. 6 is an image view of the creation processing in FIG. 5.

FIG. 7 is a diagram illustrating pattern examples of line segment creation processing.

FIG. 8 is a configuration block diagram of a modification of the construction model creation system according to the first embodiment.

FIG. 9 is a flowchart of model creation processing according to the same modification.

FIG. 10 is an image view of singular point processing according to the same modification.

FIG. 11 is a configuration block diagram of a construction model creation system according to a second embodiment.

FIG. 12 is an example of a member shape database in the same system.

FIG. 13A is an example of a construction model database in the same system. FIG. 13B is another example of the construction model database in the same system.

FIG. 14 is a creation flowchart of a construction model creating method according to the second embodiment.

FIG. 15 is a flowchart of a main reinforcement model creating method 1 according to the second embodiment.

FIG. 16 is an image view of creation processing in FIG. 15.

FIG. 17 is a flowchart of singular point processing according to a modification of the main reinforcement model creating method 1 in FIG. 15.

FIG. 18 is a flowchart of a hoop model creating method 1 according to the second embodiment.

FIG. 19 is an image view of creation processing in FIG. 18.

FIG. 20 is a flowchart of singular point processing according to a modification of the hoop model creating method 1 in FIG. 18.

FIG. 21 is a flowchart of a main reinforcement model creating method 2 according to the second embodiment.

FIG. 22 is an image view of creation processing in FIG. 21.

FIG. 23 is a flowchart of a hoop model creating method 2 according to the second embodiment.

FIG. 24 is an image view of creation processing in FIG. 23.

FIG. 25 is a flowchart of a hoop model creating method 3 according to the second embodiment.

FIG. 26 is an image view of creation processing in FIG. 25.

FIG. 27 is a configuration block diagram of a construction model creation system according to a third embodiment.

FIG. 28A is an example of a drawing database in the same system. FIG. 28B is another example of the drawing database in the same system.

FIG. 29 is a creation flowchart of a construction model creating method according to the third embodiment.

FIG. 30 is a flowchart illustrating work results extraction processing in the same construction model creating method.

FIG. 31 is a configuration block diagram of a construction inspection system according to a fourth embodiment.

FIG. 32 is an example of a drawing database in the same system.

FIG. 33 is an example of an inspection results database in the same system.

FIG. 34 is an inspection flowchart of a construction inspecting method according to the fourth embodiment.

FIG. 35 is a work image view of correspondence establishment in the same construction inspecting method.

FIG. 36 is a diagram comparing a construction inspection according to the fourth embodiment and a conventional construction inspection.

### DESCRIPTION OF EMBODIMENTS

Next, preferred embodiments of the present invention will be described with reference to the drawings.

### First Embodiment

### (Construction Model Creation System)

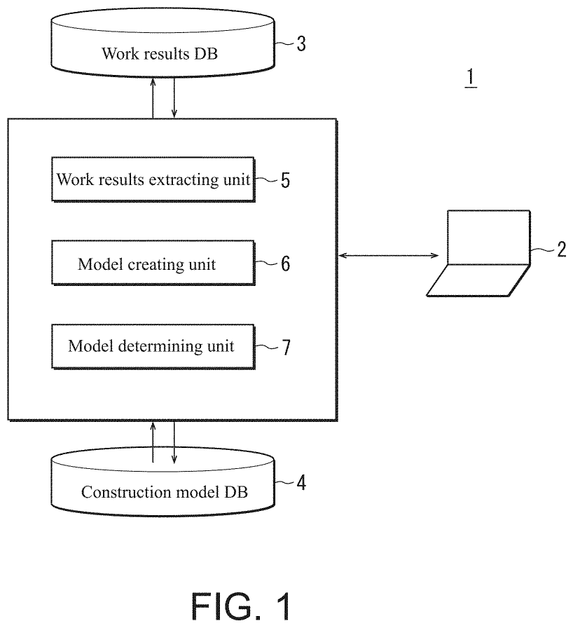

FIG. 1 is a configuration block diagram of a construction model creation system 1 according to a first embodiment of the present invention. The construction model creation system 1 includes an input/output device 2, a work results database 3, a construction model database 4, a work results extracting unit 5, a model creating unit 6, and a model determining unit 7.

The input/output device 2 is a general-purpose personal computer, a tablet terminal, or the like including at least a computing unit, a storage unit, a communication unit, a display unit, and an operation unit, and can be operated by a creator.

Each of the functional units of the work results extracting unit 5, the model creating unit 6, and the model determining unit 7 consists of electronic circuits of a CPU (Central Processing Unit), an ASIC (Application Specific Integrated Circuit), or a PLD (Programmable Logic Device) such as an FPGA (Field Programmable Gate Array). Each functional unit is configured inside the input/output device 2 or by either of separate external hardware/software. In the latter case, each functional unit can transmit and receive information to and from the input/output device 2 through a network. However, operations of the work results extracting unit 5, the model creating unit 6, and the model determining unit 7 may be manually performed.

The work results database 3 and the construction model database 4 are stored in a server computer configured to be capable of making communication through a network. This server computer can communicate with the input/output device 2 and a functional unit concerned, and can transmit and receive information to and from these.

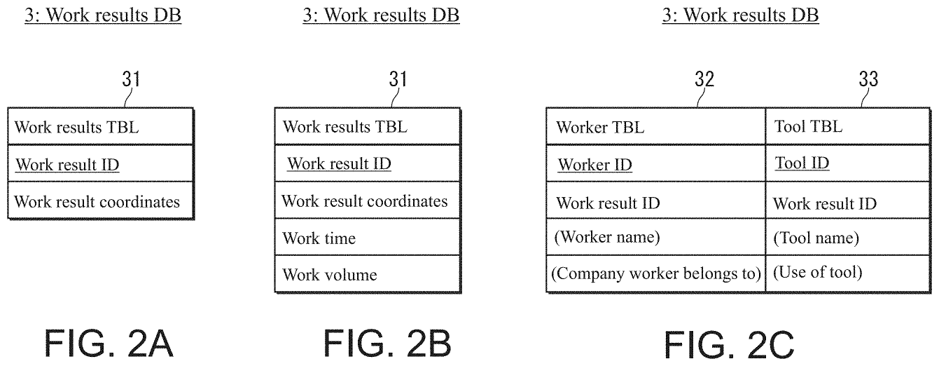

The work results database 3 includes a work results table 31 storing data on constructed portions for each of which a worker performed a work with a tool (hereinafter, referred to as “work points.” However, the work points may be stored as information not on “points” but on “a line” and “a surface,” and when the “work points” includes these, the “work points” can be read as “work results.”). The work results table 31 stores, as illustrated in FIG. 2A, at least identification information (work results ID) of a work point and three-dimensional position coordinates of the work point (work results coordinates) in association with each other.

The work results database 3 may be manually created, but is preferably automatically created by a work management system (Japanese Patent Application No. 2020-080480). The same work management system includes a tool having a communication unit and a trigger switch, a camera unit including a communication unit, a camera, a posture detecting device, and a prism, and a surveying instrument including a communication unit, a tracking unit, a distance measuring unit, and an angle measuring unit, and when detecting that the trigger switch was used, collects camera posture information obtained by the posture detecting device, a tool image obtained by the camera, position coordinates of the prism measured by the surveying instrument, and orientation information of the camera unit as viewed from the surveying instrument, and obtains and stores tip end position coordinates of the tool. Accordingly, data on a work point (particularly, tip end position coordinates of the tool) are acquired simultaneously and concurrently with the construction work, and the work results database 3 is automatically created.

It is also preferable that the work results table 31 of the work results database 3 stores a work time as attributes information in association with the work results as illustrated in FIG. 2B. Accordingly, the work results extracting unit 5 can perform extraction according to the work time. It is also preferable that the work results table 31 of the work results database 3 also stores a work volume in association with the work results. Accordingly, for example, if a tool used for a construction work is a reinforcing bar binder, the model creating unit 6 can calculate a diameter of arranged reinforcement bars to be bound from the number of wires used for binding.

It is also preferable that the work results database 3 further includes a worker table 32 and a tool table 33 as attributes information as illustrated in FIG. 2C. The worker table 32 stores identification information (worker ID) of a worker in association with a work results ID. Further, as an element for identifying the worker, information on a worker name and a company that the worker belongs to may be added. The worker table 32 enables the work results extracting unit 5 to perform extraction according to worker information. The tool table 33 stores identification information of a tool (tool ID) in association with the work results ID. Further, as an element for identifying the tool, information on a tool name and use of the tool may be added. The tool table 33 enables the work results extracting unit 5 to perform extraction according to tool information.

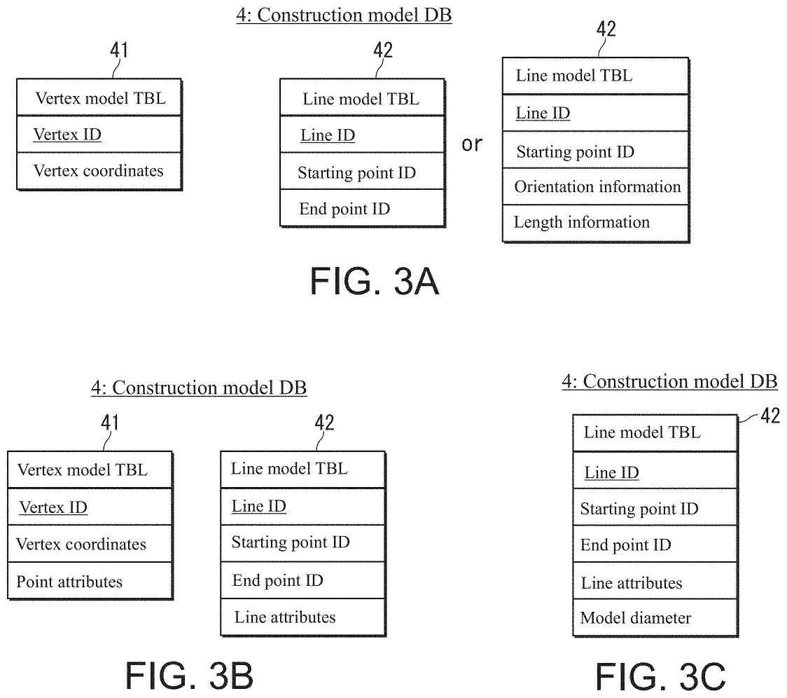

Next, in the construction model database 4, data on a “construction model” of a construction work created based on work results are stored. The construction model database 4 includes, as illustrated in FIG. 3A, at least a vertex model table 41 related to vertexes of the construction model, and a line model table 42 related to lines of the construction model.

The vertex model table 41 stores at least identification information (vertex ID) and vertex coordinates of each vertex of the construction model in association with each other.

A line model table 42 stores, for example, for each line of the construction model, identification information (line ID), identification information of a start point (start point ID) of the line, and identification information of an end point (end point ID) of the line in association with each other. However, because a line can be composed of vector information of the line, the line model table 42 can also be composed of, for example, a line ID, a start point ID, orientation information, and length information associated with each other.

It is also preferable that the vertex model table 41 stores “point attributes” in association with the information as illustrated in FIG. 3B. Similarly, it is also preferable that the line model table 42 stores “line attributes” in association with the information. Accordingly, how a certain point or a certain line was used in model creation processing can be identified, so that model creation processing of the model creating unit 6 can be smoothly performed.

It is also preferable that model diameter information of the construction model is added into the line model table 42 as illustrated in FIG. 3C. Accordingly, the model creating unit 6 can cause the construction model to have information on a bar arrangement diameter.

The construction model database 4 can include a shape model table, etc., for shapes other than lines in addition to the line model table 42.

The construction model database 4 may be manually created, but is preferably automatically created by the work results extracting unit 5, the model creating unit 6, and the model determining unit 7. The work results extracting unit 5, the model creating unit 6, and the model determining unit 7 will be described in the construction model creating method described next.

(Construction Model Creating Method According to First Embodiment)

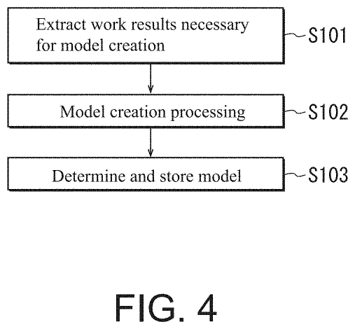

FIG. 4 is a creation flowchart of a construction model creating method according to the first embodiment.

First, in Step S101, the work results extracting unit 5 extracts work results necessary for model creation of a construction work as a model creating target from the work results database 3. For the extraction, manual selection by a creator through the input/output device 2 is possible, however, automatic extraction upon narrowing-down based on the attributes information (work time, worker information, and tool information) described above is preferable.

Next, the processing shifts to Step S102, and the model creating unit 6 performs model creation processing based on work points extracted in Step S101 (hereinafter, referred to as “extracted work results”). Details of this processing will be described later. When the model creating unit 6 finishes processing for all of the work points, the processing shifts to Step S103.

When the processing shifts to Step S103, the model determining unit 7 determines determined elements of the model created by the model creating unit 6 as a construction model of the construction work, and stores information on the construction model in a corresponding portion of the construction model database 4.

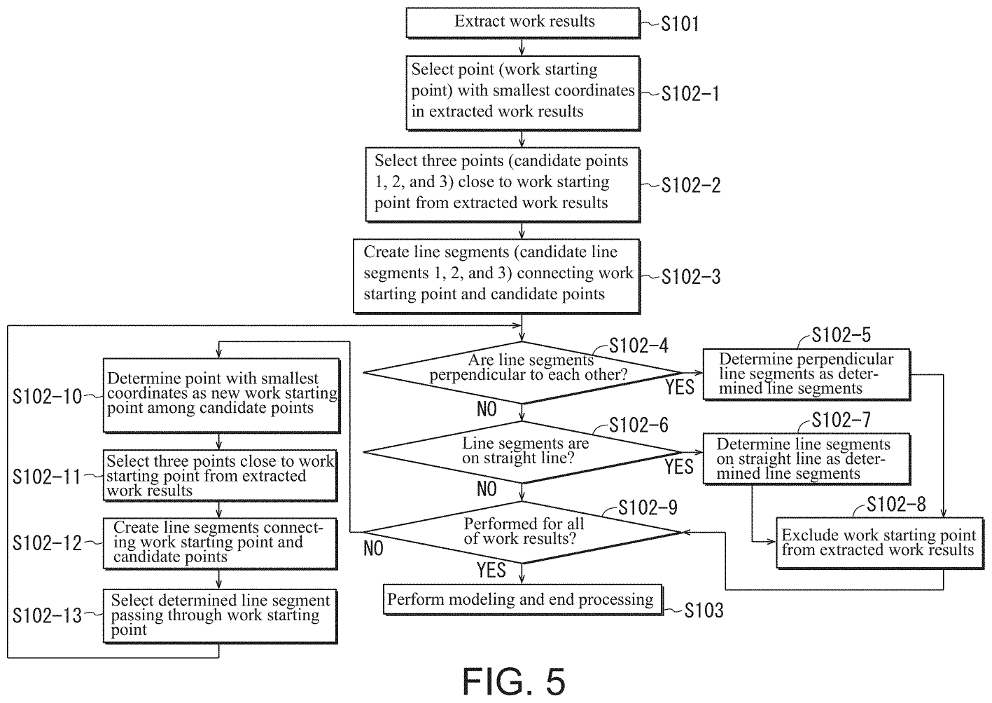

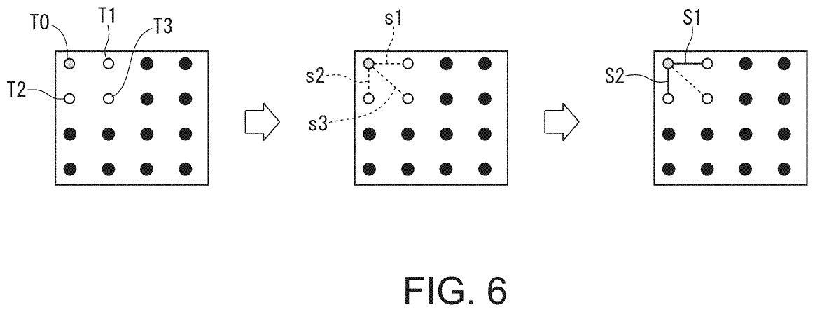

FIG. 5 is a detailed flowchart of model creation processing by the model creating unit 6 in the same construction model creating method, and FIG. 6 is an image view of the creation processing in FIG. 5.

When the extracted work results are extracted in Step S101, first, in Step S102-1, the model creating unit 6 selects a point with the smallest coordinates as a “work starting point” (TO in FIG. 6) from the extracted work results extracted in Step S101.

Next, in Step S102-2, the model creating unit 6 selects three points in order of increasing distance of coordinates from the work starting point as “candidate point 1, candidate point 2, and candidate point 3” (T1, T2, and T3 in FIG. 6) from the extracted work results.

Next, in Step S102-3, the model creating unit 6 selects line segments connecting the work starting point and the candidate points 1, 2, and 3 as “candidate line segment 1, candidate line segment 2, and candidate line segment 3” (s1, s2, and s3 in FIG. 6).

Next, in Step S102-4, whether the line segments are perpendicular to each other is determined. When the line segments are perpendicular to each other (YES), the processing shifts to Step S102-5, and the perpendicular line segments are determined as “determined line segments” (S1 and S2 in FIG. 6), and the processing shifts to Step S102-8. When the line segments are not perpendicular to each other (NO), the processing shifts to Step S102-6.

When the processing shifts to Step S102-6, whether the line segments are on a straight line is determined. When the line segments are on a straight line (YES), the processing shifts to Step S102-7, and the line segments on a straight line are determined as “determined line segments” and the processing shifts to Step S102-8. When the line segments are not on a straight line (NO), the processing shifts to Step S102-9.

When the processing shifts to Step S102-8, the work starting point selected in Step S102-1 is excluded from the extracted work results.

Next, the processing shifts to Step S102-9, and whether the processing has been performed for all of the extracted work results is determined. When the processing is not finished for all of the results (NO), the processing shifts to Step S102-10, and a point with the smallest coordinates is selected as a new “work starting point” among the candidate points 1, 2, and 3.

Next, the processing shifts to Step S102-11, and from the extracted work results, three points in order of increasing distance of coordinates from the new work starting point are selected as new “candidate point 1, candidate point 2, and candidate point 3.”

Next, in Step S102-12, line segments connecting the new work starting point and the candidate points 1, 2, and 3 are selected as new “candidate line segment 1, candidate line segment 2, and candidate line segment 3.”

Next, in Step S102-13, a line segment that passes through the new work starting point and has already been determined as a determined line segment is selected, and the processing shifts to Step S102-4, and whether the new “candidate line segment 1, candidate line segment 2, and candidate line segment 3” are perpendicular to this determined line segment is determined, and this flow is repeated.

On the other hand, in Step S102-9, when the processing is finished for all of the extracted work results (YES), the processing shifts to Step S103.

In Step S103, the model determining unit 7 determines the “determined line segments” as “determined elements,” and stores the determined elements as a construction model (bar arrangement model) of the construction work in the construction model database 4. Specifically, the model determining unit 7 stores vertexes, start points, and end points (or orientations and lengths), etc., of the determined line segments in corresponding portions of the vertex model table 41 and the line model table 42 of the construction model database 4. At this time, it is also preferable that the model determining unit 7 stores a difference between a work starting point/a candidate point as “point attributes” in the vertex model table 41. Similarly, it is also preferable that a difference between a candidate line segment/a determined line segment as “line attributes” in the line model table 42.

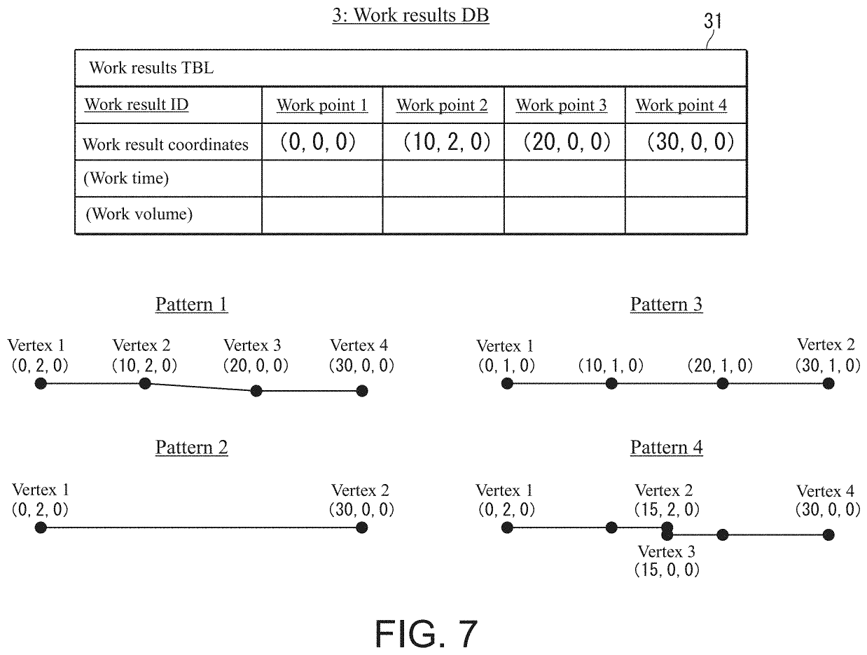

For creation of line segments in Step S102, a plurality of patterns may be set. FIG. 7 is a diagram illustrating pattern examples of line segment creation processing. The model creating unit 6 models line segments based on, for example, the following patterns.
(Pattern 1) A determined line segment is created by using the same coordinates as those of work points in the work results table 31 as vertexes.
(Pattern 2) A determined line segment is created by using a starting point and an end point of work points as vertexes.
(Pattern 3) A line segment passing through an average position of the respective work points is created as a determined line segment.
(Pattern 4) Line segments divided in an allowable range are respectively created as determined line segments.

(Effect According to First Embodiment)

As described above, by the construction model creation system 1 and creating method of the present embodiment, based on work points (work results) for which a worker performed a construction work at a construction site, a construction model of the construction work is automatically generated.

In a conventional method, to obtain a construction model, a construction was done, a measurement of the construction work was done, and then a construction model was created from the measurement. However, according to the present embodiment, a construction model is automatically created based on work results. Therefore, the measurement of the construction work is no longer required, and it also becomes possible to obtain a construction model simultaneously with the construction work.

Moreover, in the conventional method, because a construction model was obtained based on measurement data obtained by reflected light reception by a laser scanner so that measurements of a transparent member such as glass, a member with a high reflective index such as light-gauge steel and a member with a small member area, were difficult, and model automatic creation was difficult. However, according to the present embodiment, a construction model is created based on coordinate information of work points for which a construction was performed in actuality, so that a construction model can be created regardless of properties of the member.

(Singular Point Processing)

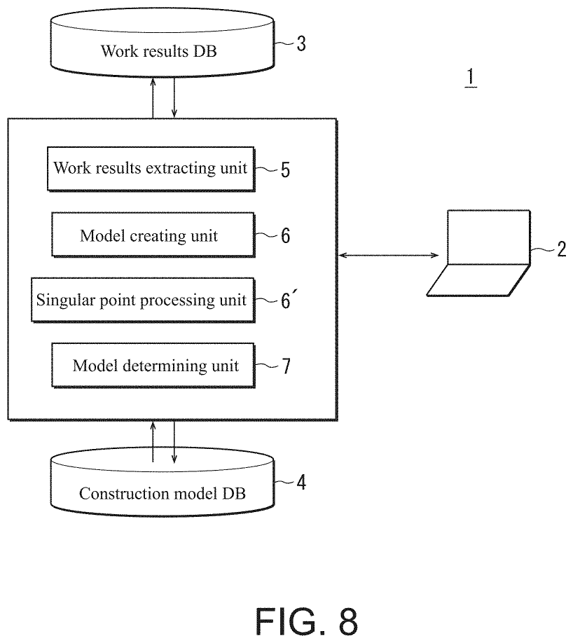

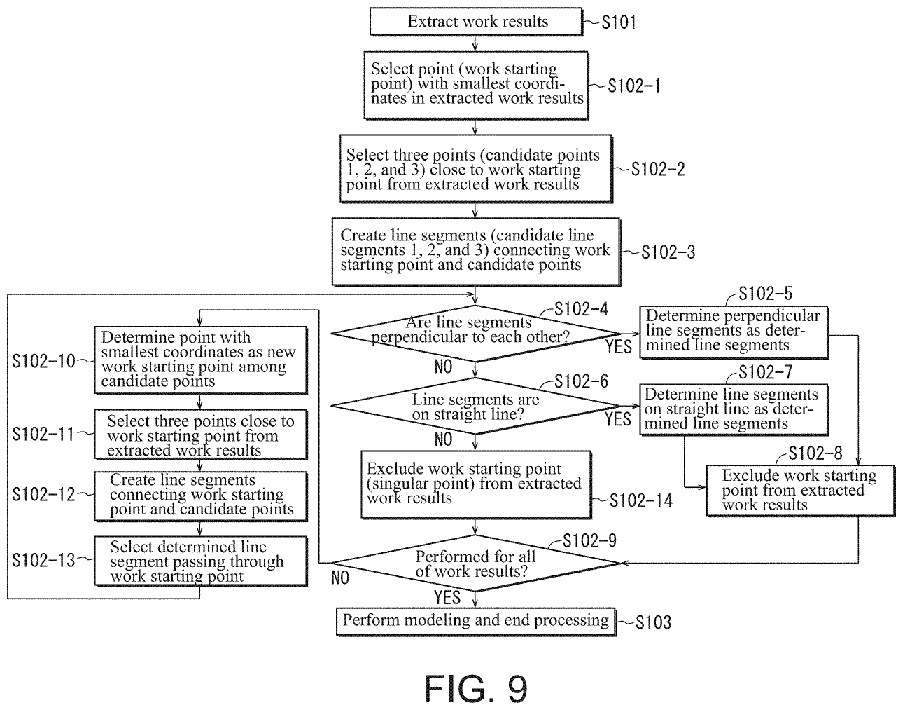

Next, a preferred modification of the first embodiment will be described. FIG. 8 is a configuration block diagram of a modification of the construction model creation system 1 according to the first embodiment, and FIG. 9 is a flowchart of model creation processing according to the same modification.

The construction model creation system 1 according to the modification further includes a singular point processing unit 6′ as illustrated in FIG. 8.

In a construction model creating method according to the modification, as illustrated in FIG. 9, when it is determined that the line segments are not on a straight line (NO) in Step S102-6, the processing shifts to Step S102-14 and the singular point processing unit 6′ functions. The singular point processing unit 6′ performs processing by regarding a work starting point in creation processing being currently executed as being foreign to this creation processing so as to exclude the work starting point from the extracted work results and treat this work starting point as point attributes of “singular point” in the model determining unit 7.

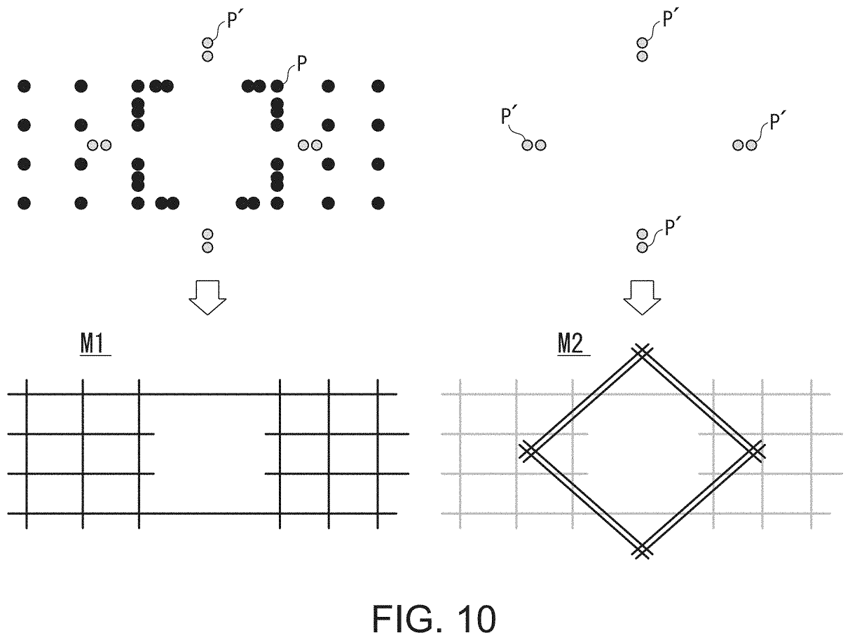

FIG. 10 is an image view of singular point processing. In FIG. 10, gray points are points (P′) subjected to singular point processing, and black points are points (P) not subjected to singular point processing. From the points (P), a construction model (M1) is created. On the other hand, when the work results extracting unit 5 extracts only the points (P′) from point attributes of “singular point” and sets the points (P′) as new extracted work results, and the model creating unit 6 performs model creation processing, a construction model (M2) different from the construction model (M1) is created. In this way, by providing point attributes of “singular point” by the singular point processing unit 6′, a construction model of a different pattern can be automatically recursively generated.

### Second Embodiment

### (Construction Model Creation System)

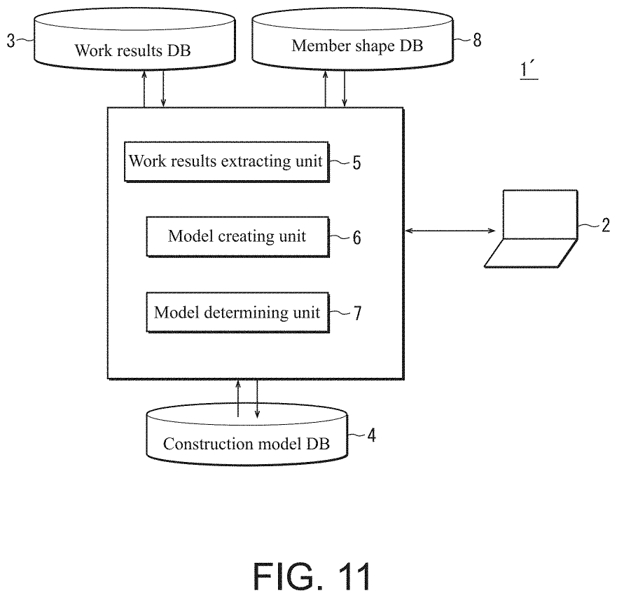

FIG. 11 is a configuration block diagram of a construction model creation system 1′ according to a second embodiment of the present invention. The same components as in the first embodiment are provided with the same reference signs, and descriptions of these are omitted.

The construction model creation system 1′ further includes a member shape database 8 for smoothing model creation.

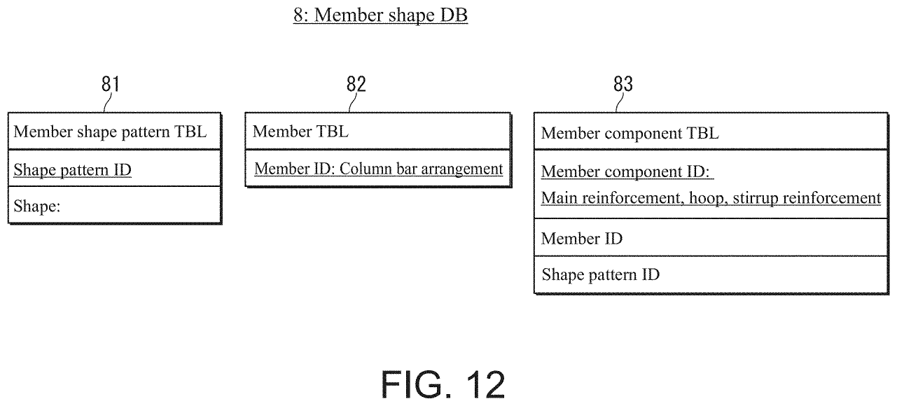

In the member shape database 8, data on shape patterns of construction members are stored. As illustrated in FIG. 12, the member shape database 8 includes a member shape pattern table 81 storing identification information (shape pattern ID) and shape information of a specific shape pattern of a construction member, a member table 82 storing a structure classification of the construction member (member ID: column bar arrangement/beam bar arrangement, etc.), and a member component table 83 storing a component classification (member component ID: main reinforcement/hoop/stirrup reinforcement, etc.) of the construction member in association with the member ID and the shape pattern ID. The member shape pattern table 81 includes a linear shape table, a quadrangular shape table, a circular shape table, and an L-shape table, etc. These are examples, and the tables are not limited to those described above. The member shape database 8 is associated with the work results database 3 by coordinates.

The member shape database 8 may be manually created, but is preferably automatically created by, for example, acquiring an image of bar arrangement, applying geometric configuration pattern recognition processing to the acquired image by confirmation against registered images, and registering an extracted shape pattern in association with a shape pattern ID, a member ID, and a member component ID. An image to be used for image analysis can be acquired by a work management system (Japanese Patent Application No. 2020-080480).

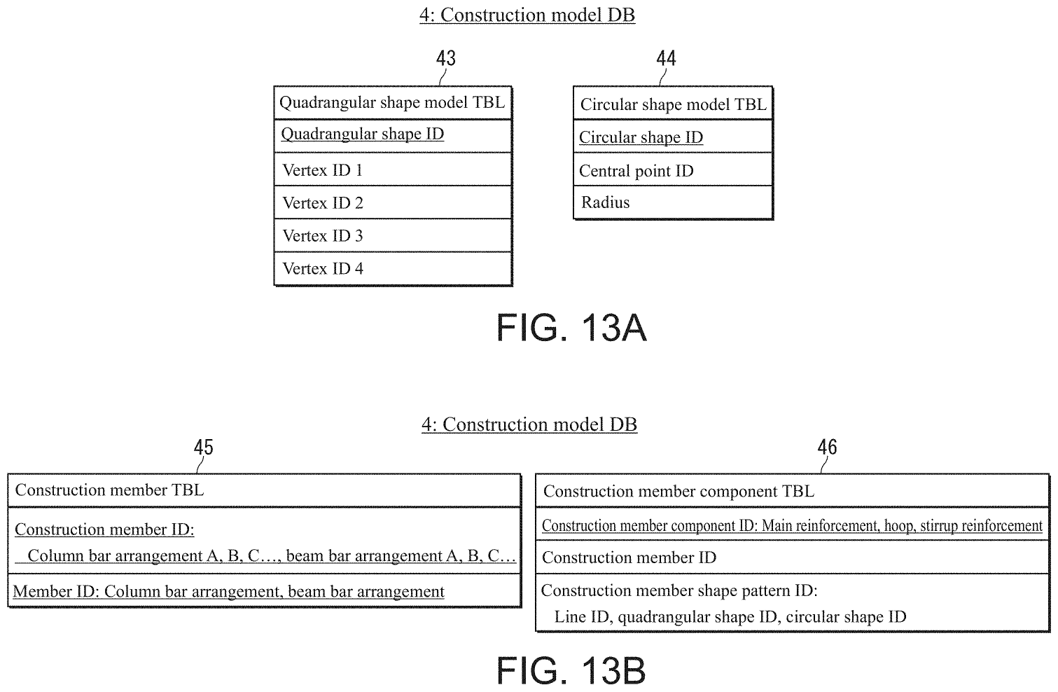

It is preferable that the construction model database 4 in the present embodiment further includes, as illustrated in FIG. 13A, a quadrangular shape model table 43 and a circular shape model table 44. The quadrangular shape model table 43 stores quadrangular shape model identification information (quadrangular shape ID) and identification information of four vertexes (vertex ID 1, vertex ID 2, vertex ID 3, and vertex ID 4) in association with each other. The circular shape model table 44 stores model identification information (circular shape ID), center point identification information (center point ID), and diameter or radius information in association with each other. These are examples, and the shape model tables are not limited to those described above. The construction model database 4 of the present embodiment preferably includes shape model tables corresponding to shape patterns that the member shape pattern table 81 includes.

It is also preferable that the construction model database 4 includes a construction member table 45 and a construction member component table 46 as illustrated in FIG. 13B. The construction member table 45 stores identification information (construction member ID) of a construction member in association with a member ID in the member shape database 8. The construction member component table 46 stores identification information (construction member component ID) of a component of the construction member, identification information of a shape pattern of the construction member (construction member shape pattern ID), and the construction member ID in association with each other. The construction member shape pattern ID is associated with a line ID in the line model table 42, a quadrangular shape ID in the quadrangular shape model table 43, or a circular shape ID in the circular shape model table 44.

(Construction Model Creating Method According to Second Embodiment)

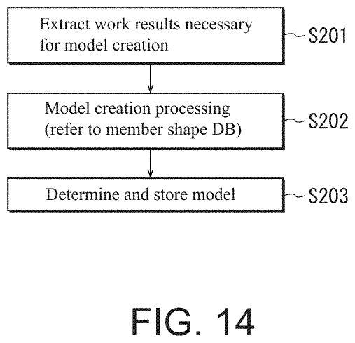

FIG. 14 is a creation flowchart of a construction model creating method according to the second embodiment. The creation flow of the present embodiment is equivalent to Steps S101 to S103 in FIG. 4 except for details. That is, in Step S201, the work results extracting unit 5 extracts work results necessary for creation of a construction model from the work results database 3, the model creating unit 6 performs model creation processing in Step S202, and in Step S203, the model determining unit 7 determines a construction model of a construction work and stores it in the construction model database 4.

However, in the present embodiment, in Step S202, member shape data in the member shape database 8 is referred to. Hereinafter, a construction model creating method according to the second embodiment, that is, an example of a construction model creating method using the member shape database 8 will be described.

Method of Estimation from Member and Structure

### “Main Reinforcement Model Creation Example No. 1”

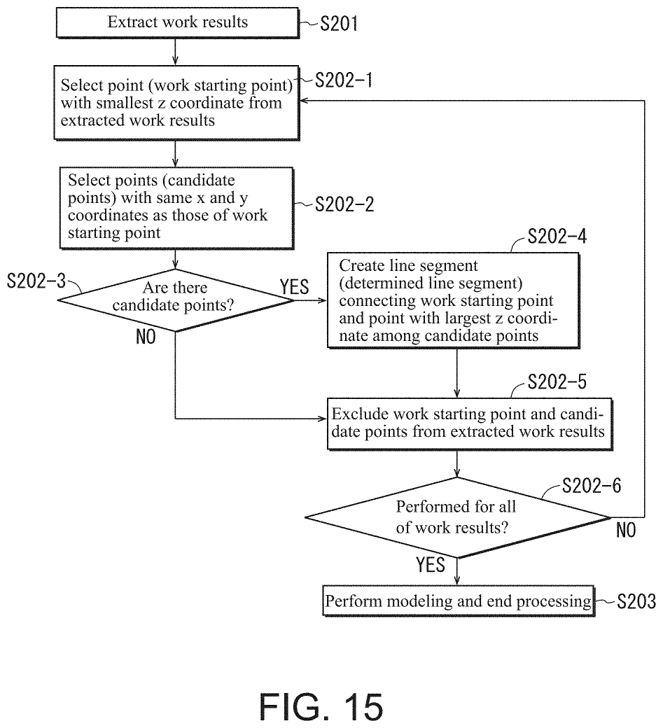

An example of creating a “main reinforcement model” having a linear shape by estimation from a construction member and a bar arrangement structure of the construction member will be described. FIG. 15 is a flowchart of a main reinforcement model creating method 1 according to the second embodiment, and FIG. 16 is an image view of creation processing in FIG. 15.

In the present embodiment, a bar arrangement structure (column bar arrangement/beam bar arrangement, etc.) of a construction model to be created is selected in advance by a creator.

When the creation processing is started, in Step S201, the work results extracting unit 5 extracts work results necessary for model creation of a construction work, from the work results database 3. For the extraction, manual section by a creator through the input/output device 2 is possible, however, automatic extraction upon narrowing-down based on the attributes information (work time, worker information, and tool information) described above is preferable.

When the extracted work results are extracted, by referring to the member table 82 and the member component table 83 of the member shape database 8, the model creating unit 6 grasps member components from the bar arrangement structure of the construction work, and grasps that the shape pattern of the “main reinforcement” among the components is a “linear shape.” Thereafter, for creating a line model, the model creating unit 6 shifts the processing to Step S202-1 and selects a point with the smallest Z coordinate as a “work starting point” (TO in FIG. 16) from the extracted work results.

Next, in Step S202-2, points having the same x and y coordinates as those of the work starting point are selected as “candidate points” (T′ in FIG. 16) from the extracted work results.

Next, in Step S202-3, whether candidate points have been found is determined. When a candidate point is found (YES), the processing shifts to Step S202-4, and when no candidate point is found (NO), the processing shifts to Step S202-5.

When the processing shifts to Step S202-4, a line segment connecting the work starting point and the point with the largest z coordinate among the candidate points is created and determined as a “determined line segment” (S1 in FIG. 16). The line segment creation processing may be performed in the plurality of patterns illustrated in FIG. 7.

Next, the processing shifts to Step S202-5, and the work starting point and the candidate points are excluded from the extracted work results.

Next, the processing shifts to Step S202-6, and whether the processing has been performed for all of the extracted work results is determined. When the processing is not finished for all of the results (NO), a new “work starting point” is selected. On the other hand, when the processing is finished for all of the results (YES), the processing shifts to Step S203. In Step S203, the model determining unit 7 determines the “determined line segments” as “determined elements”, and stores the determined elements as a “main reinforcement construction model” in the construction model database 4.

(Singular Point Processing)

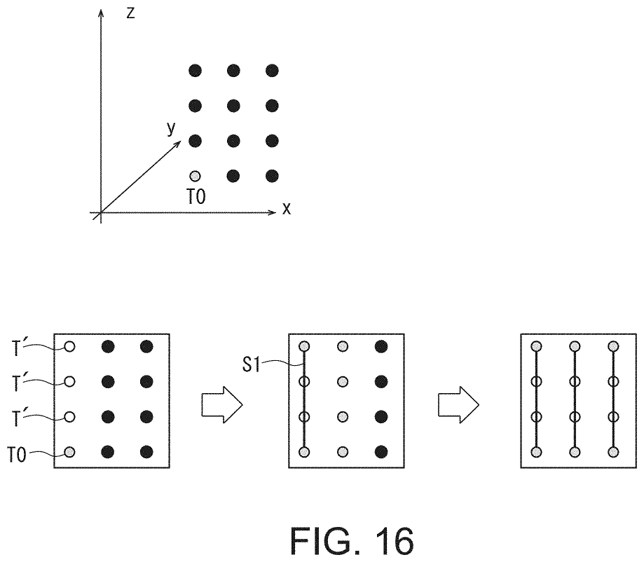

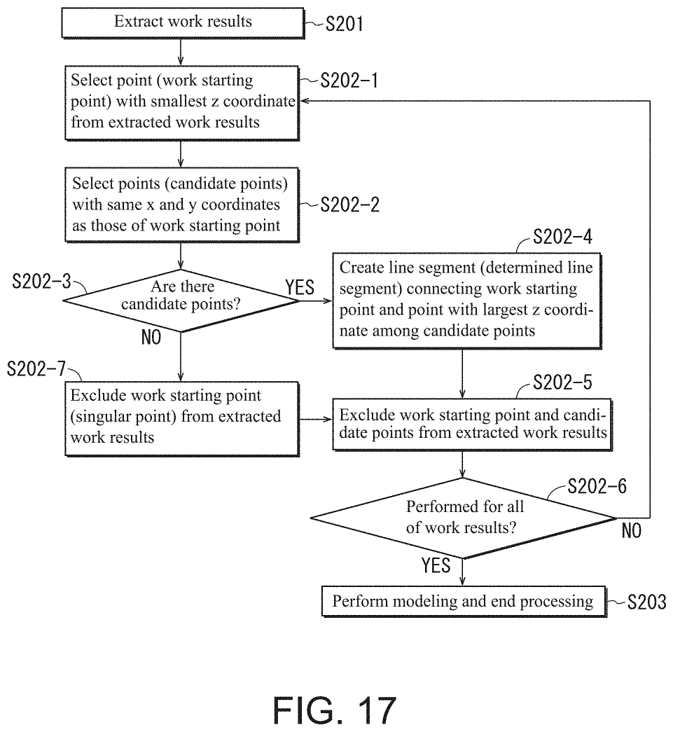

In the above-described main reinforcement creation as well, processing of the singular point processing unit 6′ is effective. FIG. 17 is a flowchart of singular point processing according to a modification of the main reinforcement model creating method 1 in FIG. 15. When no candidate point is found in Step S202-3 (NO), it is preferable that the processing shifts to Step S202-7 and the singular point processing unit 6′ functions. The singular point processing unit 6′ regards a work starting point in creation processing being currently executed as being foreign to this creation processing and excludes the work starting point from the extracted work results, and determines this work starting point as a “singular point” and then shifts the processing to Step S202-5. In Step S203, the model determining unit 7 stores this point as point attributes of “singular point.” In this modification as well, by incorporating singular point processing, a construction model of a different pattern can be automatically recursively generated.

Method of Estimation from Member and Structure

### “Hoop Model Creation Example No. 1”

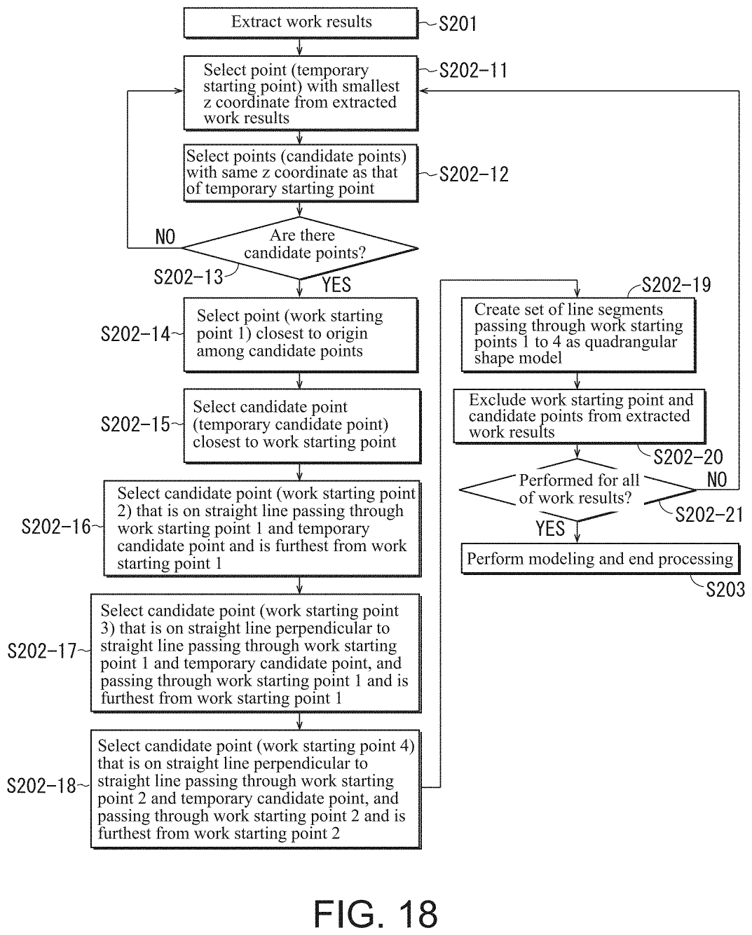

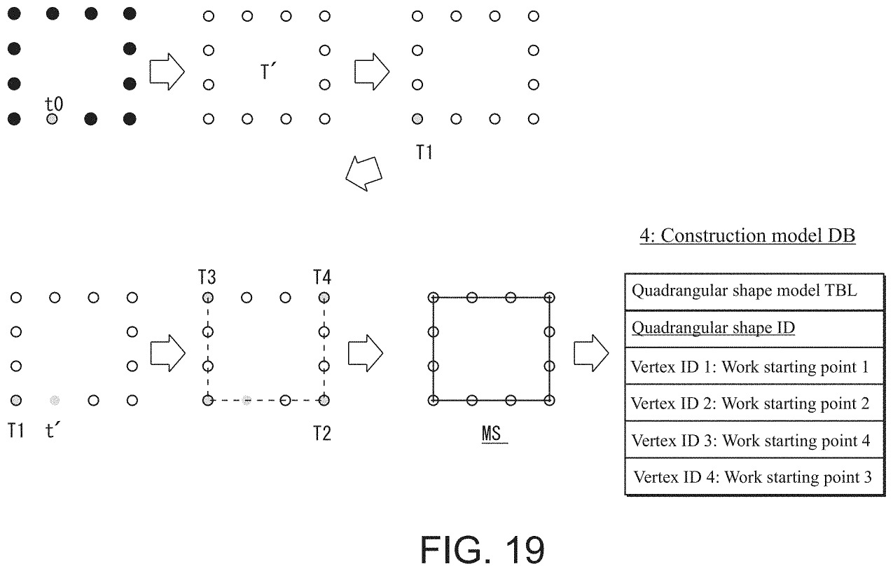

An example of creating a “hoop model” having a quadrangular shape by estimation from a construction member and a bar arrangement structure of the construction member will be described. FIG. 18 is a flowchart of a hoop model creating method 1 according to the second embodiment, and FIG. 19 is an image view of creation processing in FIG. 18.

In the present embodiment, a bar arrangement structure (column bar arrangement/beam bar arrangement, etc.) of a construction model to be created is selected in advance by a creator.

When creation processing is started, in Step S201, the work results extracting unit 5 extracts work results necessary for model creation of a construction work as a model creating target from the work results database 3. For the extraction, manual selection by a creator through the input/output device 2 is possible, however, automatic extraction upon narrowing-down based on the attributes information described above is preferable.

When the extracted work results are extracted, by referring to the member table 82 and the member component table 83 of the member shape database 8, the model creating unit 6 grasps member components from the bar arrangement structure of the construction model to be created, and grasps that the shape pattern of a “hoop” among the components is a “quadrangular shape.” Thereafter, for creating a quadrangular shape model, the model creating unit 6 shifts the processing to Step S202-11, and selects a point with the smallest z coordinate as a “temporary starting point” (t0 in FIG. 19) from the extracted work results.

Next, in Step S202-12, from the extracted work results, points with the same x and y coordinates as those of the temporary starting point are selected as “candidate points” (T′ in FIG. 19).

Next, in Step S202-13, whether candidate points have been found is determined. When a candidate point is found (YES), the processing shifts to Step S202-14, and when no candidate point is found (NO), the processing returns to Step S202-11, and a temporary starting point is selected again.

When the processing shifts to Step S202-14, among the candidate points, a point closest to the origin of the x, y, and z axes is selected as a “work starting point 1” (T1 in FIG. 19).

Next, the processing shifts to Step S202-15, and a candidate point closest to the work starting point 1 is selected as a “temporary candidate point” (t′ in FIG. 19).

Next, the processing shifts to Step S202-16, and a candidate point that is on a straight line passing through the work starting point 1 and the temporary candidate point and is furthest from the work starting point 1 is selected as a “work starting point 2” (T2 in FIG. 19).

Next, the processing shifts to Step S202-17, and a candidate point that is on a straight line perpendicular to the straight line passing through the work starting point 1 and the temporary candidate point, and passing through the work starting point 1 (T1) and is furthest from the work starting point 1 is selected as a “work starting point 3” (T3 in FIG. 19).

Next, the processing shifts to Step S202-18, and a candidate point that is on a straight line perpendicular to the straight line passing through the work starting point 1 and the temporary candidate point, and passing through the work starting point 2 (T2) and is furthest from the work starting point 2 is selected as a “work starting point 4” (T4 in FIG. 19).

Next, the processing shifts to Step S202-19, and a set of line segments passing through the work starting points 1 to 4 (T1 to T4) is created as a quadrangular shape model (MS in FIG. 19).

Next, the processing shifts to Step S202-20, and the work starting points (T1 to T4) and the candidate points (T′) are excluded from the extracted work results.

Next, the processing shifts to Step S202-21, and whether the processing has been performed for all of the extracted work results is determined. When the processing is not finished for all of the results (NO), the processing returns to Step S202-11, and a new “temporary starting point” is selected. On the other hand, when the processing is finished for all of the results (YES), the processing shifts to Step S203. In Step S203, the model determining unit 7 determines the “quadrangular shape models” as “determined elements” and stores the determined element as a “hoop construction model” in the construction model database 4.

(Singular Point Processing)

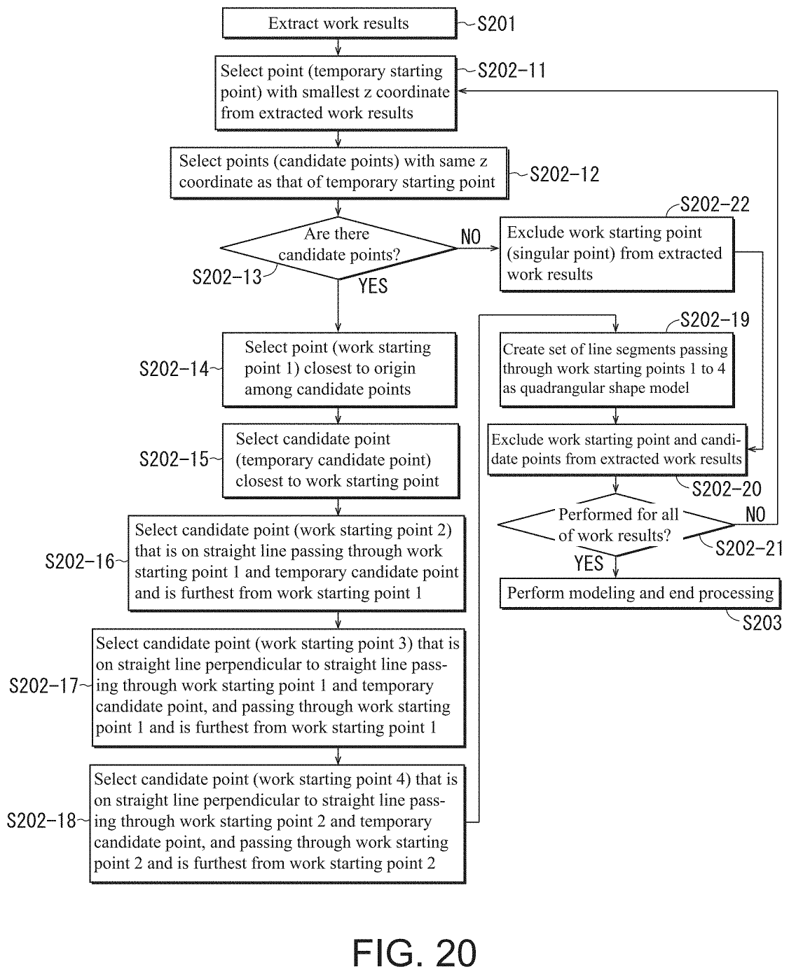

In the above-described hoop creating method as well, processing of the singular point processing unit 6′ is effective. FIG. 20 is a flowchart of singular point processing according to a modification of the hoop model creating method 1 in FIG. 18. When no candidate is found in Step S202-13 (NO), it is preferable that the processing shifts to Step S202-22 and the singular point processing unit 6′ functions. The singular point processing unit 6′ regards a work starting point in creation processing being currently executed as being foreign to this creation processing and excludes this work starting point from the extracted work results and determines this work starting point as a “singular point” and then shifts the processing to Step S202-20. In Step S203, the model determining unit 7 stores this point as point attributes of “singular point.” In this modification as well, by incorporating the singular point processing, a construction model of a different pattern can be automatically recursively generated.

Method of Estimation Using Grouping by Plane Projection

### “Main Reinforcement Model Creation Example No. 2”

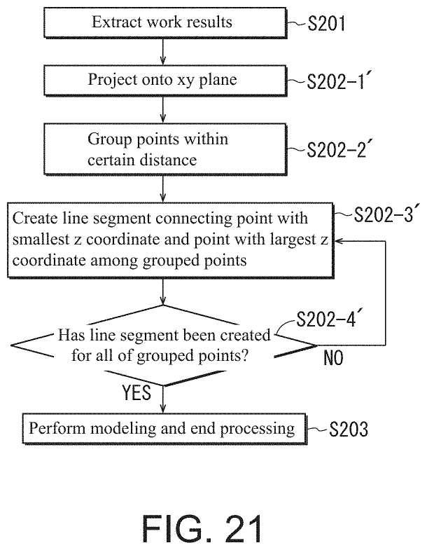

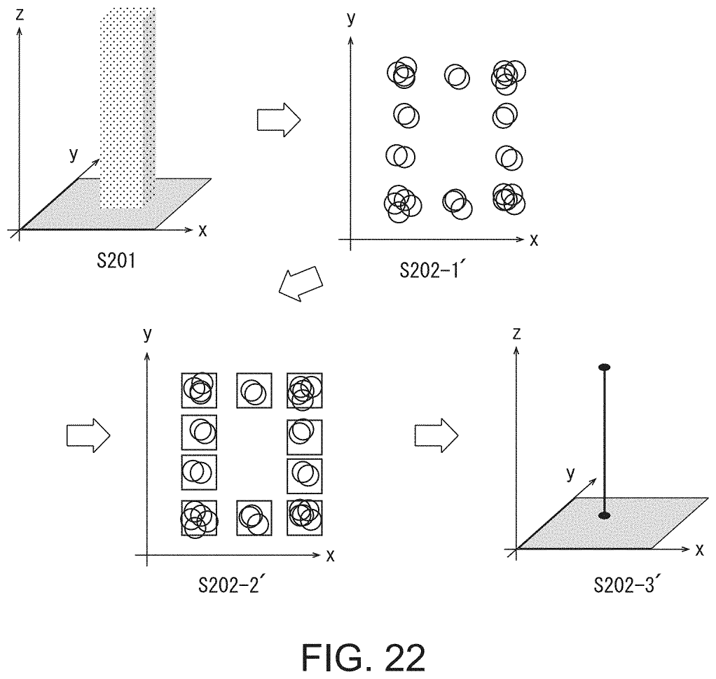

An example of creating a “main reinforcement model” having a linear shape by estimation using grouping by plane projection will be described. FIG. 21 is a flowchart of a main reinforcement model creating method 2 according to the second embodiment, and FIG. 22 is an image view of creation processing in FIG. 21.

In the present embodiment, a bar arrangement structure (column bar arrangement/beam bar arrangement, etc.) of a construction model to be created is selected in advance by a creator.

When the creation processing is started, in Step S201, the work results extracting unit 5 extracts work results necessary for model creation of a construction work, from the work results database 3. For the extraction, manual selection by the creator through the input/output device 2 is possible, however, automatic extraction upon narrowing-down based on the attributes information described above is preferable.

When the extracted work results are extracted, by referring to the member table 82 and the member component table 83 of the member shape database 8, the model creating unit 6 grasps member components from a bar arrangement structure of the construction model to be created, and grasps that the shape pattern of the “main reinforcement” among the components is a “linear shape.” Thereafter, for creating a line model, the model creating unit 6 shifts the processing to Step S202-1′ and projects the extracted work results onto an x-y plane (refer to S202-1′ in FIG. 22).

Next, the processing shifts to Step S202-2′, and points within a certain distance are grouped (refer to S202-2′ in FIG. 22).

Next, the processing shifts to Step S202-3′, and a line segment connecting a point with the smallest z coordinate and a point with the largest z coordinate among the grouped points is created and determined as a “determined line segment” (refer to S202-3′ in FIG. 22). The line segment creation processing may be performed in the plurality of patterns illustrated in FIG. 7.

Next, the processing shifts to Step S202-4′, and whether line segment creation has been performed for all of the grouped points is determined. When the line segment creation is not finished for all of the points (NO), the processing returns to Step S202-3′, and remaining line segments are created. On the other hand, when the line segment creation is finished for all of the points (YES), the processing shifts to Step S203. In Step S203, the model determining unit 7 determines the “determined line segments” as “determined elements,” and stores the determined elements as a “main reinforcement construction model” in the construction model database 4.

Method of Estimation Using Grouping by Plane Projection

### “Hoop Model Creation Example No. 2”

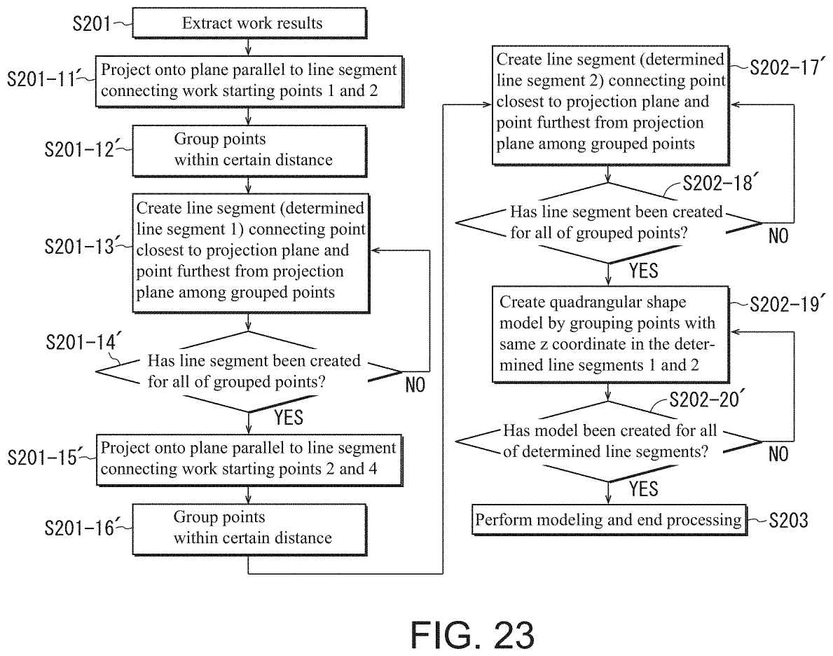

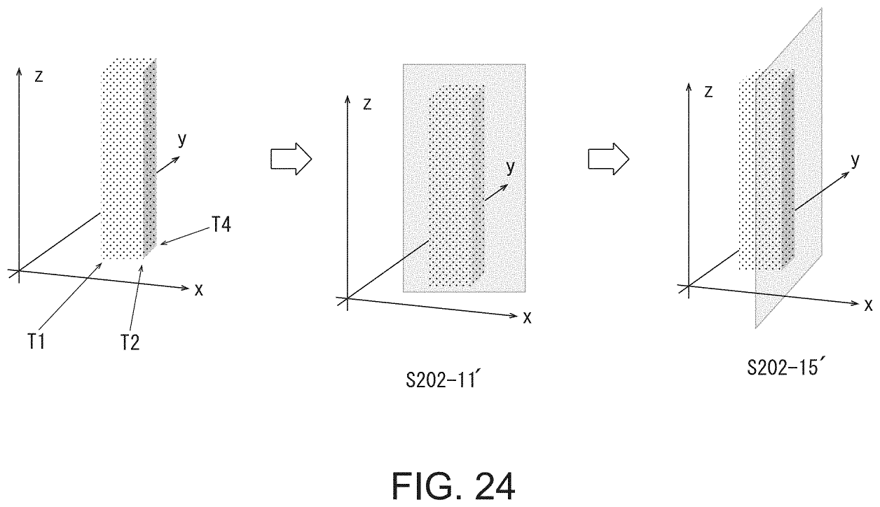

An example of creating a “hoop model” having a quadrangular shape by estimation using grouping by plane projection will be described. FIG. 23 is a flowchart of a hoop model creating method 2 according to the second embodiment, and FIG. 24 is an image view of creation processing in FIG. 23. Processing equivalent to that in the hoop model creation No. 1 is represented by quoting the same step number.

In the present embodiment, a bar arrangement structure (column bar arrangement/beam bar arrangement, etc.) of a construction model to be created is selected in advance by a creator.

When the creation processing is started, in Step S201, the work results extracting unit 5 extracts work results necessary for model creation of a construction work from the work results database 3. For the extraction, manual selection by the creator through the input/output unit 2 is possible, however, automatic extraction upon narrowing-down based on the attributes information described above is preferable.

When the extracted work results are extracted, by referring to the member table 82 and the member component table 83 of the member shape database 8, the model creating unit 6 grasps member components from the bar arrangement structure of the construction model, and grasps that the shape pattern of a “hoop” among the components is a “quadrangular shape.” Thereafter, for creating a quadrangular shape model, the model creating unit 6 shifts the processing to Step S202-11′ and projects the extracted work results onto a plane parallel to a line segment connecting the “work starting point 1” selected in Step S202-14 and the “work starting point 2” selected in Step S202-16 (refer to S202-11′ in FIG. 24).

Next, the processing shifts to Step S202-12′, and points within a certain distance are grouped.

Next, the processing shifts to Step S202-13′ and a line segment connecting a point closest to the projection plane and a point furthest from the projection plane among the grouped points is created and determined as a “determined line segment 1.”

Next, the processing shifts to Step S202-14′, and whether the line segment creation has been performed for all of the grouped points is determined. When the line segment creation is not finished for all of the points (NO), the processing returns to Step S202-13′, and remaining line segments are created. On the other hand, when the line segment creation is finished for all of the points (YES), the processing shifts to Step S202-15′.

When the processing shifts to Step S202-15′, then, the extracted work results are projected onto a plane parallel to a line segment connecting the “work starting point 2” selected in Step S202-16 and the “work starting point 4” selected in Step S202-18 (refer to S202-15′ in FIG. 24).

Next, the processing shifts to Step S202-16′, and points within a certain distance are grouped.

Next, the processing shifts to Step S202-17′, and a line segment connecting a point closest to the projection plane and a point furthest from the projection plane among the grouped points is created and determined as a “determined line segment 2.”

Next, the processing shifts to Step S202-18′, and whether the line segment creation has been performed for all of the grouped points is determined. When the line segment creation is not finished for all of the points (NO), the processing returns to Step S202-17′, and remaining line segments are created. On the other hand, when the line segment creation is finished for all of the points (YES), the processing shifts to Step S202-19′.

When the processing shifts to Step S202-19′, points with the same z coordinate in the determined line segments 1 and 2 are grouped to create a “quadrangular shape model.”

Next, the processing shifts to Step S202-20′, and whether a quadrangular shape model has been created for all of the determined line segments is determined. When the creation is not finished for all of the determined line segments (NO), the processing returns to Step S202-19′, and remaining models are created. On the other hand, when the creation is finished for all of the determined line segments (YES), the processing shifts to Step S203. In Step S203, the model determining unit 7 determines the “quadrangular shape models” as “determined elements” and stores the determined elements as a “hoop construction model” in the construction model database 4.

Method of Estimation Using Grouping by Plane Projection

### “Hoop Model Creation Example No. 3”

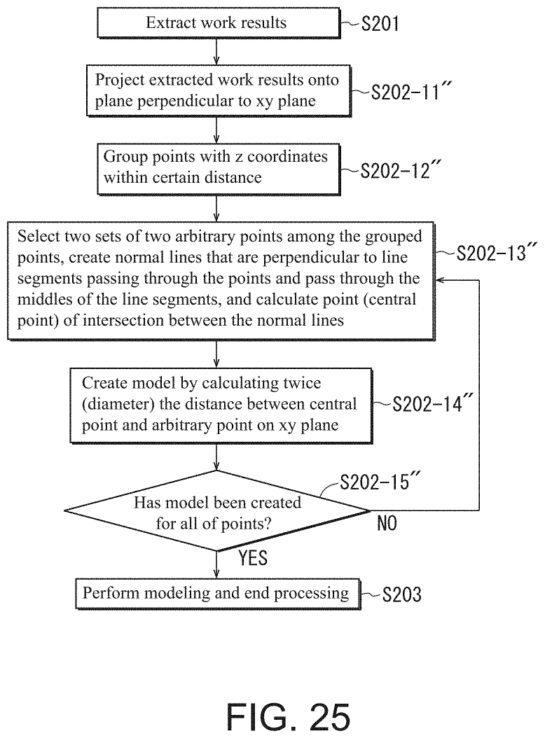

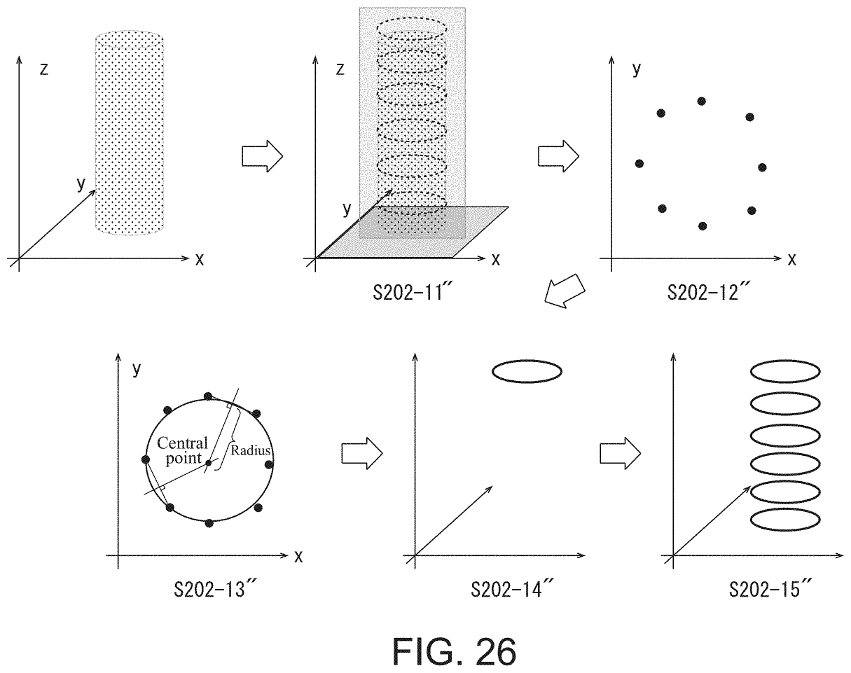

An example of creating a “hoop model” having a circular shape by estimation using grouping by plane projection will be described. FIG. 25 is a flowchart of a hoop model creating method 3 according to the second embodiment, and FIG. 26 is an image view of creation processing in FIG. 25.

In the present embodiment, a bar arrangement structure (column bar arrangement/beam bar arrangement, etc.) of a construction model to be created is selected in advance by a creator.

When the creation processing is started, in S201, the work results extracting unit 5 extracts work results necessary for model creation of a construction work from the work results database 3. For the extraction, manual selection by the creator through the input/output device 2 is possible, however, automatic extraction upon narrowing-down based on the attributes information described above is preferable.

When the extracted work results are extracted, by referring to the member table 82 and the member component table 83 of the member shape database 8, the model creating unit 6 grasps member components from the bar arrangement structure of the constriction model to be created, and grasps that the shape pattern of a “hoop” among the components is a “circular shape.” Thereafter, for creating a circular shape model, the model creating unit 6 shifts the processing to Step S202-11″, and projects the extracted work results onto a plane perpendicular to the x-y plane (refer to S202-11″ in FIG. 26).

Next, the processing shifts to Step S202-12″, and points with z coordinates within a certain distance are grouped (refer to S202-12″ in FIG. 26).

Next, the processing shifts to Step S202-13″, and two sets of two arbitrary points are selected among the grouped points, and normal lines that are perpendicular to line segments passing through the respective points and pass through the middles of the line segments are created, and a point of intersection between the normal lines is calculated as a “central point” (refer to S202-13″ in FIG. 26).

Next, the processing shifts to Step S202-14″, and a distance (radius) between the central point and an arbitrary point on the x-y plane is doubled to calculate a diameter, whereby a circular shape model is created (refer to S202-14″ in FIG. 26).

Next, the processing shifts to Step S202-15″, and whether the circular shape model creation has been performed for all of the grouped points is determined. When the circular shape model creation is not finished for all of the points (NO), the processing returns to Step S202-13′, and remaining models are created (refer to S202-15″ in FIG. 26). On the other hand, when the circular shape model creation is finished for all of the points (YES), the processing shifts to Step S203. In Step S203, the model determining unit 7 determines the “circular shape models” as “determined elements,” and stores the determined elements as a “hoop construction model” in the construction model database 4.

(Effect According to Second Embodiment)

As described above, according to the construction model creation system 1′ and creating method of the present embodiment, by incorporating information on member shapes (member shape database 8), the model creating unit 6 can smoothly grasp a shape of a construction member of the model creation, so that a construction model can be efficiently created.

### Third Embodiment

### (Construction Model Creation System)

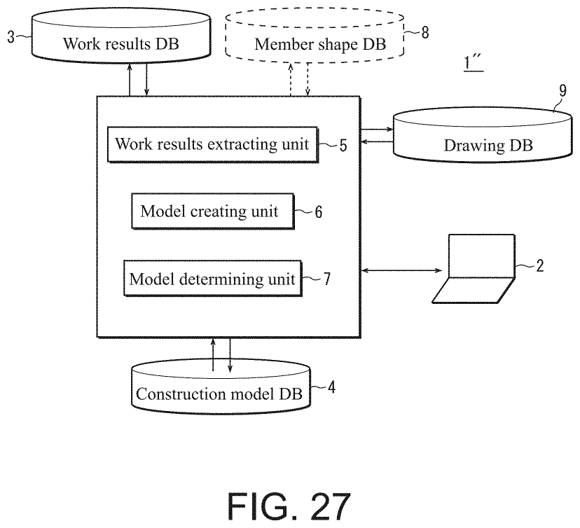

FIG. 27 is a configuration block diagram of a construction model creation system 1″ according to a third embodiment of the present invention. The same components as in the embodiments described above are provided with the same reference signs, and descriptions of these are omitted.

The construction model creation system 1″ further includes a drawing database 9 for smoothing model creation. The member shape database 8 is referred to as necessary.

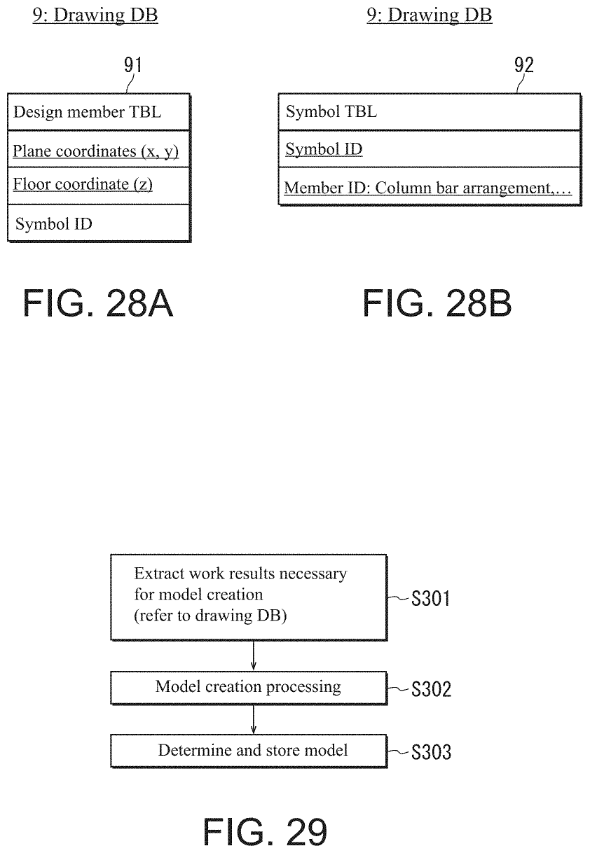

In the drawing database 9, data obtained from a design drawing including a structural drawing, a construction plan document, and a two-dimensional construction drawing, etc., to be used for construction of a construction work, are stored. The drawing database 9 includes, as illustrated in FIG. 28A, at least a design member table 91 storing symbols (symbol IDs) provided for the respective members in the design drawing, and plane coordinates (x, y) and a floor coordinate (z) of each member. The drawing database 9 is associated with the work results database 3 by coordinates. Preferably, as illustrated in FIG. 28B, the drawing database 9 includes a symbol table 92 that associates the symbol IDs with the member IDs in the member shape database 8.

The drawing database 9 may be manually created, but is preferably automatically created by scanning the design drawing and acquiring information on the plane coordinates, the floor coordinate, and the symbol of each member.

(Construction Model Creating Method According to Third Embodiment)

FIG. 29 is a creation flowchart of a construction model creating method according to the third embodiment. A creation flow of the present embodiment is equivalent to Steps S101 to S103 in FIG. 4 except for details. That is, the work results extracting unit 5 extracts work results necessary for creating a construction model from the work results database 3 in Step S301, the model creating unit 6 performs model creation processing in Step S302, and the model determining unit 7 determines and stores a construction model of the construction work in the construction model database 4 in Step S303.

However, in the present embodiment, data in the drawing database 9 are referred to in Step S301.

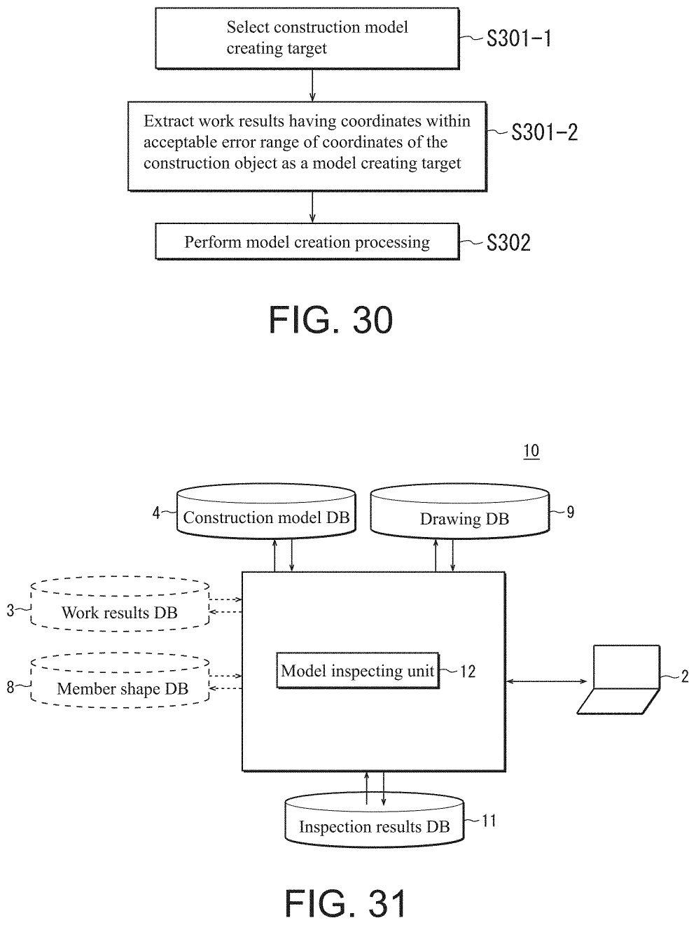

FIG. 30 is a flowchart illustrating work results extraction processing in the same construction model creating method.

In Step S301-1, first, a creator selects in advance a construction work for a model creation based on the drawing database 9. At this time, the construction work is preferably selected based on a symbol ID or a member ID, etc. In the case of selection based on a member ID, etc., the construction model creation system 1″ refers to the member shape database 8 as well.

Next, in Step S301-2, the work results extracting unit 5 refers to the work results database 3, and automatically extracts work results having coordinates within an acceptable error range of coordinates of the construction member for the model creation.

Thereafter, the model creating unit 6 functions, and in Step S302, performs the model creation processing of the first embodiment (FIGS. 5,and 9) or the second embodiment (FIGS. 15, 17, 18, 20, 21, 23, and 25). When the model creation processing of the second embodiment is performed in Step S302, the construction model creation system 1″ refers to the member shape database 8 as well.

(Effect According to Third Embodiment)

As described above, according to the construction model creation system 1″ and creating method of the present embodiment, by incorporating information from the design drawing (drawing database 9), the work results extracting unit 5 can efficiently extract work points necessary for model creation, and accordingly, a construction model can be efficiently created.

### Fourth Embodiment

### (Construction Inspection System)

A construction inspection system according to the present embodiment conducts a construction quality inspection by utilizing the construction model database 4 created by the construction model creation system described above.

FIG. 31 is a configuration block diagram of a construction inspection system 10 according to the fourth embodiment of the present invention. The same components as in the embodiments described above are provided with the same reference signs, and descriptions of these are omitted.

The construction inspection system 10 includes, as essential components, an input/output device 2, a construction model database 4, a drawing database 9, an inspection results database 11, and a model inspecting unit 12. As arbitrary components, the construction inspection system 10 includes a work results database 3 and a member shape database 8. The work results database 3 and the member shape database 8 are referred to as necessary.

The input/output device 2 is a general-purpose personal computer, a tablet terminal, or the like including at least a computing unit, a storage unit, a communication unit, a display unit, and an operation unit, and can be operated by an inspector.

The model inspecting unit 12 consists of electronic circuits of a CPU, an ASIC, or a PLD such as an FPGA, etc. Each functional unit may be configured inside the input/output device 2 or by either of separate external hardware or software. In the latter case, the model inspecting unit 12 can transmit and receive information to and from the input/output device 2 through a network.

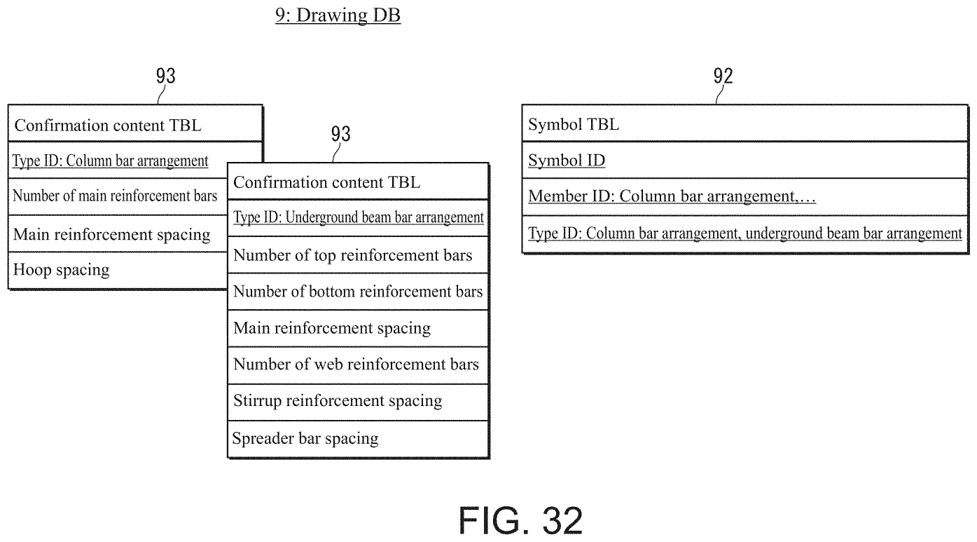

The drawing database 9 of the present embodiment includes, as illustrated in FIG. 32, a confirmation content table 93 obtained from a design drawing. The confirmation content table 93 stores identification information (type ID) concerning a bar arrangement type (column bar arrangement/underground beam bar arrangement, etc.) and required design information (the number of main reinforcement bars/main reinforcement spacing/the number of top reinforcement bars/the number of bottom reinforcement bars, the number of web reinforcement bars/stirrup reinforcement spacing/spreader bar spacing, etc.). The symbol table 92 stores the symbol IDs, the member IDs, and the type IDs in association with each other.

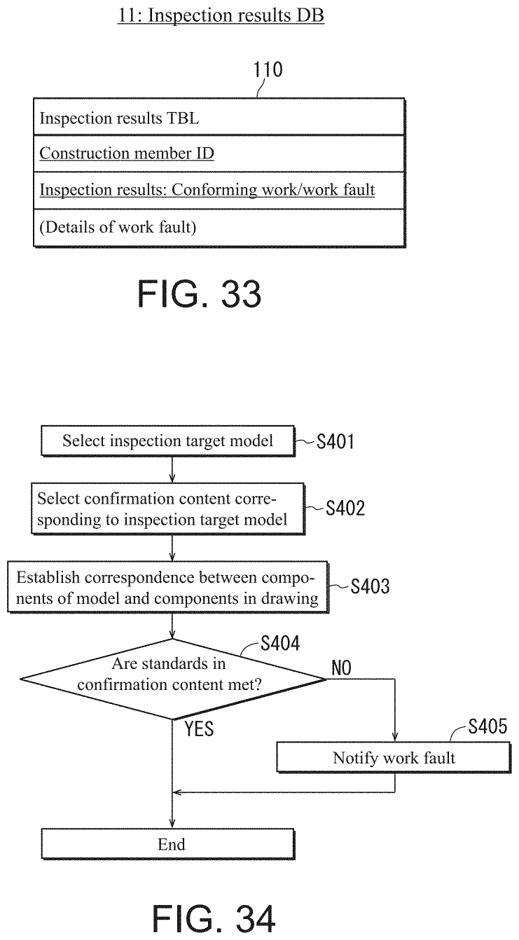

In the inspection results database 11, data on results of an inspection of an inspection target model conducted by comparing the construction model stored in the construction model database 4 with the design drawing, are stored. The inspection results database 11 includes an inspection results table 110 storing, as illustrated in FIG. 33, at least a construction member ID and inspection results (conforming work/work fault). The inspection results table 110 can also store details of a work fault, for example, an insufficient number of hoops or a hoop spacing exceeding an allowable error value based on the inspection results.

(Construction Inspecting Method)

FIG. 34 is an inspection flowchart of a construction inspecting method according to the fourth embodiment.

First, in Step S401, an inspector selects a construction model to be inspected (hereinafter, referred to as an inspection target model) from the construction model database 4. At this time, it is preferable to perform narrowing-down based on attributes information (work time/worker information/tool information, etc.) and a construction member ID (column bar arrangement A/beam bar arrangement B, etc.).

Next, in Step S402, the inspector selects confirmation content corresponding to the inspection target model from the confirmation content table 93 in the drawing database 9. Because the drawing database 9 has coordinates information, it is also possible to select confirmation content based on vertex coordinates of the inspection target model.

Next, the processing shifts to Step S403, and the model inspecting unit 12 functions. The model inspecting unit 12 establishes a correspondence between components of an inspection target model and components of a member in the design drawing, for example, as follows.

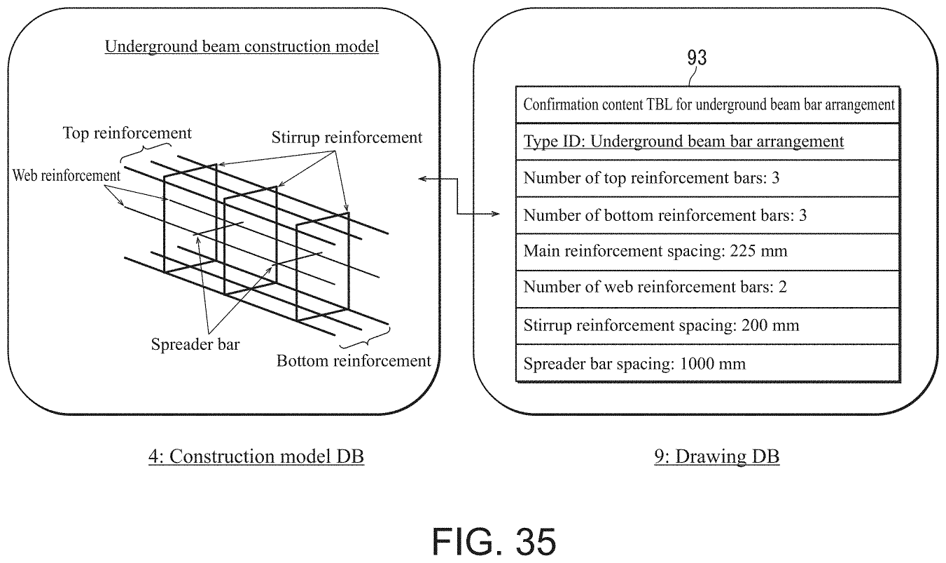

FIG. 35 is a work image view in the same construction inspecting method. In FIG. 35, a confirmation content table 93 created from a design drawing of a certain underground beam bar arrangement, and a construction model of the same underground beam bar arrangement, are illustrated. The model inspecting unit 12 establishes a correspondence, for example, as follows.
* Top reinforcement=set of line models with the largest z coordinate
* Bottom reinforcement=set of line models with the smallest z coordinate
* Auxiliary axial reinforcement=Set of line models parallel to the line models of top and bottom reinforcement bars, other than the top and bottom reinforcement bars
* Stirrup reinforcement=set of quadrangular shape models
* Spreader bar=set of line models perpendicular to auxiliary axial reinforcement When a line segment is created according to the pattern 4 (FIG. 7) and is divided, the number of arranged reinforcement bars does not match the number described in the design drawing, so that synthesis processing is preferably performed in advance.

Next, the processing shifts to Step S404, and the model inspecting unit 12 confirms whether the standards described in the confirmation content are met based on the correspondence of the contents. In the example illustrated in FIG. 35, for example, a quantity of each member, a spacing of each member, etc., are inspected. When the standards are met (YES), inspection results “conforming work” are stored in the inspection results database 11, and then the processing ends. On the other hand, when the standards are not met (NO), the processing shifts to Step S405, and “work fault” is stored in the inspection results database 11, and the inspector is notified of the work fault.

In Step S405, as notification, for example, display on an inspection terminal or site terminal, sending an e-mail, and sounding an alarm, etc., are possible, however, the notification is not limited to these. When the work results database 3 can be referred to, it is also possible that a worker is identified and notification of the information on the identified worker is given to the site in real time.

(Operation and Effect According to Fourth Embodiment)

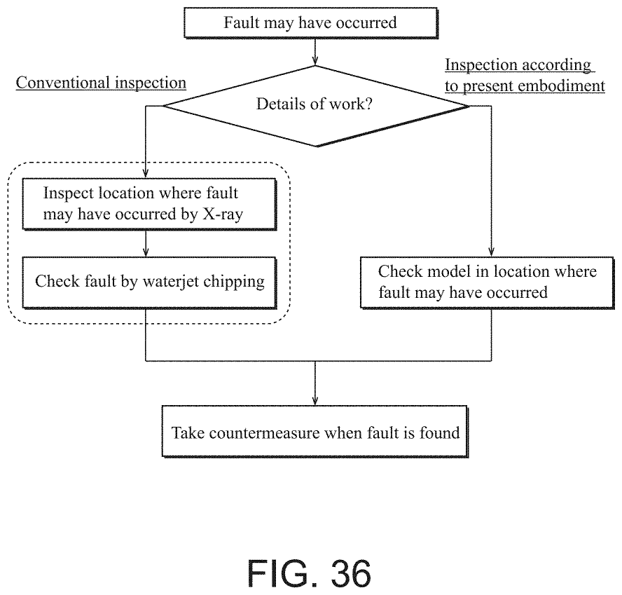

FIG. 36 is a diagram comparing the construction inspection according to the fourth embodiment and a conventional construction inspection. For example, when there is a possibility of a fault in bar arrangement after placing concrete, conventionally, an elaborate work of going to the site and inspecting a location where a fault may have occurred by X-ray and damaging the location by waterjet to confirm the fault is required, and therefore, the fault confirmation is costly and causes a delay in construction. On the other hand, in the case of the construction inspection of the present embodiment, a location where a fault may have occurred is inspected by software processing, so that without going to the site and without damaging the construction work, the presence of the fault can be confirmed. Therefore, work efficiency of the construction quality inspection is significantly improved.

In addition, in the case of the construction inspection of the present embodiment, if attributes information of work points are created, a worker and a work time, etc., of the location having a fault can also be extracted, and therefore, who did what and when can be traced later, and traceability can also be ensured.

In addition, conventionally, as an intermediate inspection of a construction work, confirming reinforcement bars one by one at the site caused a heavy workload, and therefore, a “sampling inspection” by sampling a part of the reinforcement bars was conducted. On the other hand, in the case of the construction inspection of the present embodiment, “100% inspection” can be conducted for the construction model, so that the risk of overlooking a fault can be reduced.

The tool related to creation of work points in the work results database 3 includes not only the reinforcing bar binder but also various tools to be used for construction works, such as an impact wrench, a welding machine, a screwdriver, a sealing gun, a tacker, a nailing machine, a riveter, a board cutter, a hammer drill, a scraper, a nibbler, and a puncher, etc. Concerning a tool capable of rotating forward and reverse like a screwdriver, information on not only “creation” but also “cancel” of work results can be stored. In addition, a member to be associated with work results can be narrowed down based on a tool used such that use of a reinforcing bar binder leads to narrowing down to a reinforcement member, and use of a drill leads to narrowing down to an anchor bolt. Depending on the kind of tool such as a board cutter, a spray gun, etc., information not on “points” but on “lines” or “surfaces” can be stored.

Although the preferred embodiments and modifications of the present invention have been described above, the above embodiments and modifications can be combined based on the knowledge of a person skilled in the art, and such combined embodiments are also included in the scope of the present invention.

### REFERENCE SIGNS LIST

1, 1′, 1″Model creation system
2 Input/output device
3 Work results database
4 Construction model database

5 Work results extracting unit
6 Model creating unit
6′ Singular point processing unit
7 Model determining unit
8 Member shape database
9 Drawing database
10 Construction inspection database
11 Inspection results database
12 Model inspecting unit

1. A construction model creating method creating a construction model of a construction work based on data of work results that a worker performed with a tool at a construction site.

2. A construction model creating method comprising the steps of:
by transmitting and receiving information to and from a work results database storing position coordinates of work results performed by a worker with a tool at a construction site,
(A) extracting the work results necessary for model creation of a construction work as a model creating target from the work results database;
(B) creating a model from the work results extracted in the step A; and
(C) storing a determined element of the model created in the step B as a construction model of the construction work in a construction model database.

3. The construction model creating method according to claim 2, wherein, further,
by transmitting and receiving information to and from a member shape database storing data on member shape patterns,
in the step B, with reference to the member shape database, the model is created according to a member shape of the construction work.

4. The construction model creating method according to claim 3, wherein
based on the member shape pattern stored in the member shape database, at least a linear shaped, quadrangular shaped, or circular shaped model is created in the step B.

5. The construction model creating method according to claim 2, wherein, further,
by transmitting and receiving information to and from a drawing database storing member coordinate obtained from a design drawing,
in the step A, with reference to the drawing database, the work results are extracted based on coordinates of the construction work in the design drawing.

6. The construction model creating method according to claim 2, wherein, further,
a work starting point foreign to a specific creation processing is excluded from the extracted work results extracted in the step B, and stored as a singular point in the step C, and
by using the singular point as new extracted work results, model creation processing is recursively performed.

7. The construction model creating method according to claim 2, wherein
the work results database stores attributes information of at least a work time, a worker, or a tool, and in the step A, the work results are extracted according to the attributes information.

8. A construction inspecting method comprising the steps of:
(D) selecting an inspection target model from the construction model database according to claim 2;
(E) selecting confirmation content for the inspection target model by transmitting and receiving information to and from a drawing database storing member coordinate and confirmation content obtained from a design drawing;
(F) establishing a correspondence between a component of the inspection target model and a component in the design drawing;
(G) confirming whether the component of the inspection target model meets the confirmation content for the corresponding component in the design drawing; and
(H) notifying a work fault when the confirmation content is not met in the step G.

9. A construction model creation system comprising:
a work results database storing position coordinates of work results performed by a worker with a tool at a construction site;
a work results extracting unit configured to extract the work results necessary for model creation of a construction work from the work results database;
a model creating unit configured to create a model from the work results extracted by the work results extracting unit;
a model determining unit configured to store a determined element of the model created by the model creating unit as a construction model of the construction work; and
a construction model database configured to store the construction model determined by the model determining unit.

10. The construction model creation system according to claim 9, further comprising:
a member shape database storing data on member shape patterns, wherein
the model creating unit refers to the member shape database and creates the model according to a member shape of the construction work.

11. The construction model creation system according to claim 9, further comprising:
a drawing database storing member coordinate obtained from a design drawing, wherein
the work results extracting unit refers to the drawing database and extracts the work results based on coordinates of the construction work in the design drawing.

12. The construction model creation system according to claim 9, further comprising:
a singular point processing unit configured to exclude a work starting point foreign to a specific model creation processing of the model creating unit from the work results extracted and treat the work starting point as a singular point.

13. A construction inspection system comprising: a model inspecting unit configured to select an inspection target model from the construction model database created by the construction model creation system according to claim 9, select the confirmation content from a drawing database storing member coordinate and confirmation content obtained from a design drawing, establish a correspondence between a component of the inspection target model and a component in the design drawing, confirm whether the component of the inspection target model meets the confirmation content for the corresponding component in the design drawing, and notify a work fault when the confirmation content is not met.

14. A storage medium storing a computer program of the construction model creating method according to claim 2.

15. A storage medium storing a computer program of the construction inspecting method according to claim 8.
